(19) United States
(12) Patent Application Publication
(10) Pub. No.: US 2026/0255943 A1
(43) Pub. Date: Aug. 27, 2026

(54) SEMICONDUCTOR DEVICE INCLUDING STACKED SEMICONDUCTOR CHIPS, SEMICONDUCTOR PACKAGE HAVING SEMICONDUCTOR DEVICE, AND METHOD OF MANUFACTURING SEMICONDUCTOR DEVICE

(71) Applicant: SK hynix Inc., Gyeonggi-do (KR)

(72) Inventor: Heon Yong CHANG, Gyeonggi-do (KR)

(21) Appl. No.: 19/199,639

(22) Filed: May 6, 2025

(30) Foreign Application Priority Data
Feb. 27, 2025 (KR) 10-2025-0025705

(51) Int. Cl. H01L 23/48; H01L 21/768; H01L 23/00; H01L 23/528; H01L 25/18; H10B 80/00; H10D 80/30

(52) U.S. Cl. CPC H10W 20/20; H10W 20/056; H10W 20/43; H10W 20/435; H10W 90/00; H10B 80/00; H10D 80/30; H10W 80/312; H10W 80/327; H10W 90/20; H10W 90/297; H10W 90/722; H10W 90/792

(57) ABSTRACT

A semiconductor device is provided including a first semiconductor chip including a first substrate, a first circuit layer disposed on the first substrate and a first chip pad disposed on the first circuit layer; a second semiconductor chip bonded onto the first semiconductor chip, and including a second substrate, a second circuit layer disposed under the second substrate and a second chip pad disposed under the second circuit layer; and a through electrode penetrating the first semiconductor chip and the second semiconductor chip, and connected to the first chip pad and the second chip pad.

### CROSS-REFERENCE TO RELATED APPLICATION

The present application claims priority under 35 U.S.C. § 119(a) to Korean Patent Application No. 10-2025-0025705 filed on Feb. 27, 2025, which is incorporated herein by reference in its entirety.

### BACKGROUND

### 1. Technical Field

Embodiments of the present disclosure relate generally to a semiconductor technology, and more particularly, to a semiconductor device including stacked semiconductor chips, a semiconductor package having a semiconductor device, and a method of manufacturing a semiconductor device.

### 2. Related Art

Modern electronic products are required to process large volumes of data while becoming increasingly more compact in size to meet consumer demands. Accordingly, there is a growing need to increase the degree of integration of semiconductor devices used in these electronic products. Because it is difficult to satisfy required functions with just a single semiconductor chip due to limitations in integration technology, semiconductor packages are manufactured using a plurality of semiconductor chips.

Even when a semiconductor package includes a plurality of semiconductor chips, the semiconductor package is required to be fabricated to a specified thickness or thinner depending on the requirements of an application in which the semiconductor package is mounted.

Making semiconductor chips thinner may reduce the thickness of semiconductor packages, however, the reduced thickness may cause warpage in the semiconductor chips and defects such as chip cracks and chipping. These defects may compromise the reliability and performance of the semiconductor package. Hence, new solutions are needed.

### SUMMARY

Embodiments of the present disclosure are directed to providing a semiconductor device including stacked semiconductor chips, a semiconductor package having a semiconductor device, and a method of manufacturing a semiconductor device.

Objects of embodiments of the disclosure are not limited to those set forth herein, and other unmentioned objects would be apparent to one of ordinary skill in the art from the following description.

In an embodiment, a semiconductor device may include: a first semiconductor chip including a first substrate, a first circuit layer disposed on the first substrate and a first chip pad disposed on the first circuit layer; a second semiconductor chip bonded onto the first semiconductor chip, and including a second substrate, a second circuit layer disposed under the second substrate and a second chip pad disposed under the second circuit layer; and a through electrode penetrating the first semiconductor chip and the second semiconductor chip, and connected to the first chip pad and the second chip pad.

In an embodiment, a semiconductor package may include: a base chip; first and second semiconductor devices stacked on the base chip; and a molding section disposed on the base chip, and sealing the first and second semiconductor devices. Each of the first and second semiconductor devices includes: a first semiconductor chip including a first substrate, a first circuit layer disposed on the first substrate and a first chip pad disposed on the first circuit layer; a second semiconductor chip bonded onto the first semiconductor chip, and including a second substrate, a second circuit layer disposed under the second substrate and a second chip pad disposed under the second circuit layer; and a through electrode penetrating the first semiconductor chip and the second semiconductor chip, and connected to the first chip pad and the second chip pad.

In an embodiment, a method of manufacturing a semiconductor device may include: preparing first and second semiconductor chips each including a substrate, a circuit layer disposed on the substrate and a chip pad disposed on the circuit layer; bonding the second semiconductor chip onto the first semiconductor chip; and forming a through electrode that penetrates the first and second semiconductor chips to connect the chip pad of the first semiconductor chip and the chip pad of the second semiconductor chip.

In an embodiment, a semiconductor device may include: a first semiconductor chip including a first substrate, a first circuit layer disposed on the first substrate and a first chip pad disposed on the first circuit layer and a first bonding insulating layer disposed on the first chip pad; a second semiconductor chip bonded onto the first semiconductor chip, and including a second substrate, a second circuit layer disposed under the second substrate and a second chip pad disposed under the second circuit layer and a second bonding insulating layer disposed under the second chip pad; and a through electrode connected to the first and second chip pads via a barrier metal covering a side surface of the through electrode. The first bonding insulating layer and the second bonding insulating layer are bonded to each other.

According to the embodiments of the present disclosure, a semiconductor device, a semiconductor package and a method of manufacturing a semiconductor device, capable of reducing height, may be provided.

The effects of the disclosure are not limited to the foregoing objects, and other effects will be apparent to one of ordinary skill in the art from the following detailed description.

### BRIEF DESCRIPTION OF THE DRAWINGS

The disclosure will be more fully understood from the following detailed description and the accompanying drawings, which are provided for illustration only and are not intended to limit the disclosure.

FIG. 1 is a cross-sectional view of a semiconductor device according to an embodiment of the present disclosure.

FIG. 2 is an enlarged view of a part A of FIG. 1.

FIG. 3 is a cross-sectional view of a semiconductor device according to an embodiment of the present disclosure.

FIG. 4 is a cross-sectional view of a semiconductor package according to an embodiment of the present disclosure.

FIG. 5 is a flowchart showing a method of manufacturing a semiconductor device according to an embodiment of the present disclosure.

FIG. 6 to FIG. 17 are cross-sectional views illustrating, according to a method for manufacturing a semiconductor device according to an embodiment of the present disclosure.

### DETAILED DESCRIPTION

Embodiments of the present disclosure are described in detail with reference to the accompanying drawings. Specific structural or functional descriptions of embodiments are provided as examples to describe concepts that are disclosed in the present application. Examples or embodiments in accordance with the concepts may be carried out in various forms, and the scope of the present disclosure is not limited to the examples or embodiments described in this specification.

The cross-hatching throughout the figures illustrates corresponding or similar areas between the figures rather than indicating the materials associated with the areas.

When one element is identified as “connected” or “coupled” to another element, the elements may be connected or coupled directly or through an intervening element between the elements. When two elements are identified as “directly connected” or “directly coupled,” one element is directly connected or directly coupled to the other element without an intervening element between the two elements.

When one element is identified as “on,” “over,” “under,” or “beneath” another element, the elements may directly contact each other or an intervening element may be disposed between the elements.

Terms such as “vertical,” “horizontal,” “top,” “bottom,” “above,” “below,” “under,” “beneath,” “over,” “on,” “side,” “upper,” “uppermost,” “lower,” “lowermost,” “front,” “rear,” “left,” “right,” “column,” “row,” “level,” and other terms implying relative spatial relationship or orientation are utilized only for the purpose of ease of description or reference to a drawing and are not otherwise limiting. Other spatial relationships or orientations not shown in the drawings or described in the specification are possible within the scope of the present disclosure.

Terms such as “first” and “second” are used to distinguish between various elements and do not imply size, order, priority, quantity, or importance of the elements. For example, a first element may be named as a second element in one example, and the second element may be named as a first element in another example.

In the description, when an element included in an embodiment is described in singular form, the element may be interpreted to include a plurality of elements performing the same or similar functions.

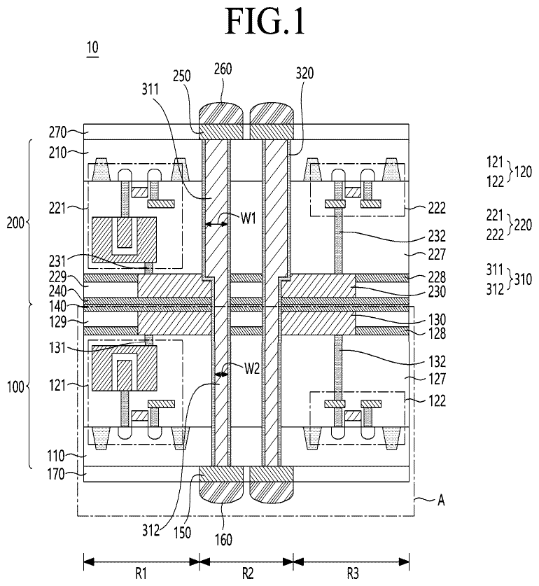

FIG. 1 is a cross-sectional view of a semiconductor device 10 according to an embodiment of the present disclosure.

Referring to FIG. 1, the semiconductor device 10 may include a first semiconductor chip 100, a second semiconductor chip 200 bonded to the first semiconductor chip 100, and a through electrode 310 (311, 312) that penetrates or passes through the first and second semiconductor chips 100 and 200. The semiconductor device 10 may further include first and second connection pads 150 and 250, first and second connection members 160 and 260, a bottom insulating layer 170, and a top insulating layer 270.

The first semiconductor chip 100 may include a first substrate 110, a first circuit layer 120 (121, 122), and first chip pads 130. The first semiconductor chip 100 may further include first and second insulating layers 127 and 129, a first etch stop layer 128, and a first bonding insulating layer 140.

The first substrate 110 may be, for example, a silicon substrate, a silicon germanium (SiGe) substrate, a gallium arsenide (GaAs) substrate, a germanium (Ge) substrate or a silicon-on-insulator (SOI) substrate.

The semiconductor device 10 may include a first region R1, a second region R2 and a third region R3. The second region R2 may be disposed between the first region R1 and the third region R3. The first circuit layer 120 may be disposed partially beneath and partially over the upper surface of the first substrate 110. The first circuit layer 120 may include a first integrated circuit 121 that is disposed in the first region R1 and a second integrated circuit 122 that is disposed in the third region R3.

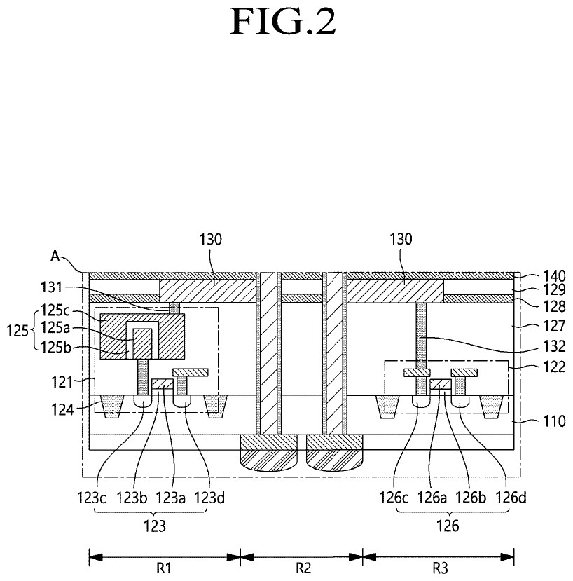

Referring to FIG. 2, the first integrated circuit 121 may include a memory cell. The memory cell may be a DRAM cell. The DRAM cell may include a cell transistor 123 and a cell capacitor 125. The cell transistor 123 may be disposed in an active region of the first substrate 110 that is defined by an isolation layer 124. The cell transistor 123 may include a first gate electrode 123a, a first gate insulating layer 123b between the first substrate 110 and the first gate electrode 123a, a first source region 123c and a first drain region 123d. The first source region 123c and the first drain region 123d are defined in the first substrate 110 on both sides of the first gate electrode 123a. The cell capacitor 125 may include a storage electrode 125a that is connected to the cell transistor 123, a plate electrode 125c, and a dielectric layer 125b disposed between the storage electrode 125a and the plate electrode 125c. The memory cell may be a DRAM cell as illustrated in FIG. 1 and FIG. 2, but the type of the memory cell is not limited thereto.

The second integrated circuit 122 may include a peripheral circuit that controls the operation of the memory cell. The peripheral circuit may include a peripheral transistor 126. The peripheral transistor 126 may be disposed in an active region of the first substrate 110 that is defined by the isolation layer 124. The peripheral transistor 126 may include a second gate electrode 126a, a second gate insulating layer 126b disposed between the first substrate 110 and the second gate electrode 126a, a second source region 126c and a second drain region 126d. The second source region 126c and the second drain region 126d are defined in the first substrate 110 on both sides of the second gate electrode 126a.

The first insulating layer 127 may be disposed on the first substrate 110 and cover the first circuit layer 120. The first etch stop layer 128 may be disposed on the first insulating layer 127 and cover the upper surface of the first insulating layer 127. The second insulating layer 129 may be disposed on the first etch stop layer 128. The first etch stop layer 128 may include an insulating material that has an etching selectivity different from the first and second insulating layers 127 and 129. The first and second insulating layers 127 and 129 may include, for example, an oxide, and the first etch stop layer 128 may include, for example, a nitride.

The first chip pads 130 may penetrate the second insulating layer 129 and the first etch stop layer 128 to contact the first insulating layer 127 and the first and second contacts 131, 132. The first chip pads 130 may include a metal material, such as, for example, tungsten (W), titanium (Ti), aluminum (Al) or copper (Cu). Although not illustrated, a barrier metal that surrounds the side surfaces and bottom surfaces of the first chip pads 130 may be further provided.

Each of the first chip pads 130 may be connected to the first circuit layer 120. As illustrated in FIG. 2, one of the first chip pads 130 (the one overlapping with the first region R1) may be connected to the first integrated circuit 121 through a first contact 131, and the other of the first chip pads 130 (the one overlapping with the third region R3) may be connected to the second integrated circuit 122 through a second contact 132.

The first bonding insulating layer 140 may be disposed on the second insulating layer 129 and the first chip pads 130. The first bonding insulating layer 140 may cover the upper surface of the second insulating layer 129 and the upper surfaces of the first chip pads 130. The first bonding insulating layer 140 may include, for example, a nitride layer.

Referring again to FIG. 1, the second semiconductor chip 200 may be a chip of the same type as the first semiconductor chip 100. The second semiconductor chip 200 may have a mirror-symmetrical structure with respect to the first semiconductor chip 100.

The second semiconductor chip 200 may include a second substrate 210, a second circuit layer 220 (221, 222) and second chip pads 230. The second semiconductor chip 200 may further include third and fourth insulating layers 227 and 229, a second etch stop layer 228 and a second bonding insulating layer 240.

The second substrate 210 may be, for example, a silicon substrate, a silicon germanium substrate, a gallium arsenide substrate, a germanium substrate or an SOI substrate.

The second circuit layer 220 may be disposed under the lower surface of the second substrate 210. The second circuit layer 220 may include a third integrated circuit 221 that is disposed in the first region R1 and a fourth integrated circuit 222 that is disposed in the third region R3. The third integrated circuit 221 may have substantially the same structure as the first integrated circuit 121. The fourth integrated circuit 222 may have substantially the same structure as the second integrated circuit 122.

The third insulating layer 227 may be disposed under the lower surface of the second substrate 210 and cover the second circuit layer 220. The second etch stop layer 228 may be disposed under the third insulating layer 227. The fourth insulating layer 229 may be disposed under the second etch stop layer 228. The second etch stop layer 228 may include an insulating material that has an etching selectivity different from the third and fourth insulating layers 227 and 229. The third and fourth insulating layers 227 and 229 may include, for example, an oxide, and the second etch stop layer 228 may include, for example, a nitride.

The second chip pads 230 may penetrate the fourth insulating layer 229 and the second etch stop layer 228 and may contact the third and fourth contacts 231 and 232. The second chip pads 230 may vertically overlap with the first chip pads 130.

The second chip pads 230 may include a metal material, such as, for example, tungsten, titanium, aluminum or copper. Although not illustrated, a barrier metal that surrounds the side surfaces and top surfaces of the second chip pads 230 may be further provided.

Each of the second chip pads 230 may be connected to the second circuit layer 220. As illustrated in FIG. 1, one of the second chip pads 230 (the one overlapping with the first region R1) may be connected to the third integrated circuit 221 through a third contact 231, and the other of the second chip pads 230 (the one overlapping with the third region R3) may be connected to the fourth integrated circuit 222 through a fourth contact 232.

The second bonding insulating layer 240 may be disposed under the fourth insulating layer 229 and the second chip pads 230. The second bonding insulating layer 240 may cover the lower surface of the fourth insulating layer 229 and the lower surfaces of the second chip pads 230. The second bonding insulating layer 240 may include, for example, a nitride layer.

The upper surface of the first bonding insulating layer 140 and the lower surface of the second bonding insulating layer 240 may be bonded to each other to form a bonding surface.

The through electrode 310 (311, 312) may penetrate the first semiconductor chip 100 and the second semiconductor chip 200. The through electrode 310 may penetrate the first substrate 110, the first insulating layer 127, the first etch stop layer 128, the second insulating layer 129, the first bonding layer 140, the second bonding layer 240, the fourth insulating layer 229, the second etch stop layer 228, the third insulating layer 227 and the second substrate 210. The through electrode 310 may be disposed in the second region R2.

The lower end of the through electrode 310 may be exposed at the lower surface of the first substrate 110. The upper end of the through electrode 310 may be exposed at the upper surface of the second substrate 210. The through electrode 310 may be connected to the first chip pad 130 and the second chip pad 230 that vertically overlap each other.

The through electrode 310 may be formed of a conductive material. A barrier metal 320 may be disposed on the side surface of the through electrode 310. The barrier metal 320 may surround the side surface of the through electrode 310. The barrier metal 320 may include a metal compound such as titanium nitride (TiN) or tantalum nitride (TaN).

The through electrode 310 may include a first section 311 and a second section 312 under the first section 311. The first section 311 of the through electrode 310 may penetrate the second substrate 210 and the third insulating layer 227. Although, in FIG. 1, the first section 311 of the through electrode 310 penetrates a partial thickness of the second chip pad 230 and the second etch stop layer 228, the first section 311 of the through electrode 310 might not penetrate the second chip pad 230 and the second etch stop layer 228.

A part of the first section 311 of the through electrode 310 may vertically overlap with the second chip pad 230. The first section 311 of the through electrode 310 may be connected to the second chip pad 230 through the barrier metal 320.

The second section 312 of the through electrode 310 may penetrate the fourth insulating layer 229, the second bonding insulating layer 240, the first bonding insulating layer 140, the second insulating layer 129, the first etch stop layer 128, the first insulating layer 127 and the first substrate 110. The second section 312 of the through electrode 310 may penetrate the bonding surface of the first semiconductor chip 100 and the second semiconductor chip 200. The second section 312 of the through electrode 310 may neighbor the side surface of the second chip pad 230 and the side surface of the first chip pad 130 with the barrier metal 320 interposed therebetween. The second section 312 of the through electrode 310 may be connected to the first and second chip pads 130 and 230 through the barrier metal 320.

Because the part of the first section 311 of the through electrode 310 overlaps with the second chip pad 230, compared to a case where the first section 311 of the through electrode 310 does not overlap with the second chip pad 230, the alignment margin between the through electrode 310 and the second chip pad 230 may be improved.

The width of the first section 311 of the through electrode 310 may be wider than the width of the second section 312. The width of the first section 311 of the through electrode 310 is W1, the width of the second section 312 of the through electrode 310 is W2, and W1 may be greater than W2.

The first connection pad 150 may be disposed under the lower end of the through electrode 310 and under the lower surface of the first substrate 110 around the lower end of the through electrode 310. The first connection pad 150 may contact the lower end of the through electrode 310, and may be electrically connected to the through electrode 310. The first connection pad 150 may be connected to the first and second chip pads 130 and 230 through the through electrode 310.

The second connection pad 250 may be disposed on the upper end of the through electrode 310 and the upper surface of the second substrate 210 around the upper end of the through electrode 310. The second connection pad 250 may contact the upper end of the through electrode 310, and may be electrically connected to the through electrode 310. The second connection pad 250 may be connected to the first and second chip pads 130 and 230 and the first connection pad 150 through the through electrode 310.

The bottom insulating layer 170 may be disposed under the lower surface of the first substrate 110. The bottom insulating layer 170 may expose the first connection pad 150. The top insulating layer 270 may be disposed on the upper surface of the second substrate 210. The top insulating layer 270 may expose the second connection pad 250.

The first connection member 160 may be disposed under the first connection pad 150. The second connection member 260 may be disposed on the second connection pad 250.

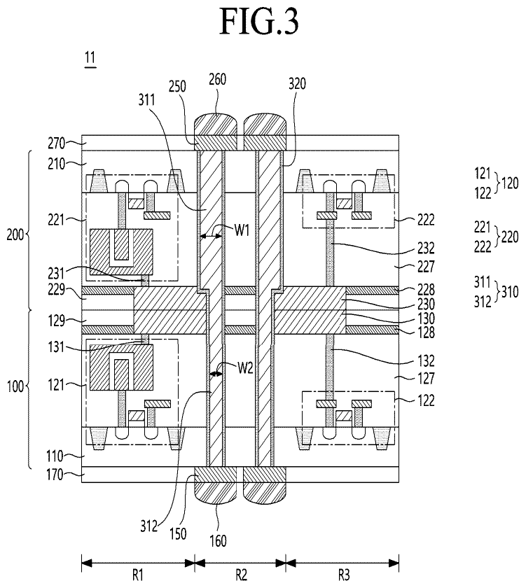

FIG. 3 is a cross-sectional view of a semiconductor device 11 according to an embodiment of the present disclosure.

Referring to FIG. 3, the semiconductor device 11 may include a first semiconductor chip 100, a second semiconductor chip 200 bonded to the first semiconductor chip 100, and a through electrode 310 that penetrates the first and second semiconductor chips 100 and 200. The semiconductor device 11 may further include first and second connection pads 150 and 250, first and second connection members 160 and 260, a bottom insulating layer 170, and a top insulating layer 270.

In the semiconductor device 11, the upper surfaces of a first chip pad 130 and a second insulating layer 129 and the lower surfaces of a second chip pad 230 and a fourth insulating layer 229 are bonded to each other to form a bonding surface.

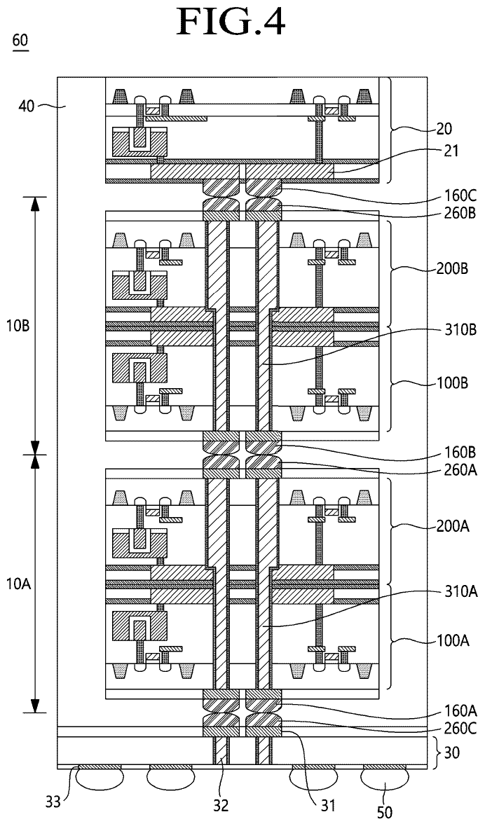

FIG. 4 is a cross-sectional view of a semiconductor package 60 according to an embodiment of the present disclosure.

Referring to FIG. 4, the semiconductor package 60 may include a first semiconductor device 10A, a second semiconductor device 10B, a third semiconductor chip 20, a base chip 30, a molding section 40, and an external connection terminal 50. The semiconductor package 60 may further include a third connection member 260C and a fourth connection member 160C.

The first semiconductor device 10A may be stacked on the base chip 30. The second semiconductor device 10B may be stacked on the first semiconductor device 10A. The third semiconductor chip 20 may be stacked on the second semiconductor device 10B. Each of the first and second semiconductor devices 10A and 10B may have substantially the same structure as the semiconductor device 10 described above with reference to FIG. 1 and FIG. 2. The first and second semiconductor devices 10A and 10B may include first semiconductor chips 100A and 100B, second semiconductor chips 200A and 200B that are bonded to the first semiconductor chips 100A and 100B, and first through electrodes 310A and 310B that penetrate the first semiconductor chips 100A and 100B and the second semiconductor chips 200A and 200B, respectively.

Although not illustrated, each of the first and second semiconductor devices 10A and 10B may have substantially the same structure as the semiconductor device 11 described above with reference to FIG. 3.

The first and second semiconductor chips 100A and 200A of the first semiconductor device 10A, the first and second semiconductor chips 100B and 200B of the second semiconductor device 10B and the third semiconductor chip 20 may be memory chips. The base chip 30 may be a logic chip for controlling the operation of the memory chips. In FIG. 4, the number of semiconductor chips that are stacked is six, but the number of semiconductor chips that are stacked may be four or more.

The base chip 30 may include a third connection pad 31, a second through electrode 32 and an external connection pad 33. The third connection pad 31 may be disposed on the upper surface of the base chip 30. The second through electrode 32 may be connected to the third connection pad 31, and may extend vertically. The external connection pad 33 may be disposed under the lower surface of the base chip 30. Although not illustrated, the base chip 30 may include a base circuit, and the external connection pad 33 may be connected to the second through electrode 32 through the base circuit.

The third connection member 260C may be disposed on the third connection pad 31. The external connection terminal 50 may be disposed under the external connection pad 33. The third connection member 260C may be a solder layer or a stacked structure of a bump and a solder layer. The external connection terminal 50 may include a solder ball.

The third semiconductor chip 20 may be of the same type as the first and second semiconductor chips 100A and 200A of the first semiconductor device 10A and the first and second semiconductor chips 100B and 200B of the second semiconductor device 10B. The third semiconductor chip 20 may include a third chip pad 21 exposed on the lower surface thereof. The fourth connection member 160C may be disposed under the third chip pad 21.

The first semiconductor device 10A may be stacked on the base chip 30 such that a first connection member 160A overlaps with the third connection member 260C. The first connection member 160A of the first semiconductor device 10A may be bonded onto the third connection member 260C.

The second semiconductor device 10B may be stacked on the first semiconductor device 10A such that a first connection member 160B overlaps with a second connection member 260A of the first semiconductor device 10A. The first connection member 160B of the second semiconductor device 10B may be bonded onto the second connection member 260A of the first semiconductor device 10A.

The third semiconductor chip 20 may be stacked on the second semiconductor device 10B such that the fourth connection member 160C overlaps with a second connection member 260B of the second semiconductor device 10B. The fourth connection member 160C may be bonded onto the second connection member 260B of the second semiconductor device 10B.

The molding section 40 may be disposed on the base chip 30, and may seal the first and second semiconductor devices 10A and 10B and the third semiconductor chip 20.

The molding section 40 may cover the side surfaces of the first and second semiconductor devices 10A and 10B and the side surface of the third semiconductor chip 20. The molding section 40 may expose the upper surface of the third semiconductor chip 20. The upper surface of the molding section 40 and the upper surface of the third semiconductor chip 20 may be on the same plane. Because the upper surface of the third semiconductor chip 20 is not covered by the molding section 40, heat generated when the first and second semiconductor devices 10A and 10B and the third semiconductor chip 20 operate may be dissipated to the outside through the upper surface of the third semiconductor chip 20 without the interference of the molding section 40.

The molding section 40 may extend to fill the spaces between the base chip 30, the first semiconductor device 10A, the second semiconductor device 10B and the third semiconductor chip 20. The molding section 40 may have the shape of a molded underfill (MUF) that fills the spaces between the base chip 30, the first semiconductor device 10A, the second semiconductor device 10B and the third semiconductor chip 20. In another example, the spaces between the base chip 30, the first semiconductor device 10A, the second semiconductor device 10B and the third semiconductor chip 20 may be filled with an underfill material different from the molding section 40. In still another example, adhesive layers may be disposed between the base chip 30 and the first semiconductor device 10A, between the first semiconductor device 10A and the second semiconductor device 10B, and between the second semiconductor device 10B and the third semiconductor chip 20.

The molding section 40 may be formed by a molding process using a liquid sealant, including, for example, an epoxy molding compound (EMC). The epoxy molding compound may include resin and filler.

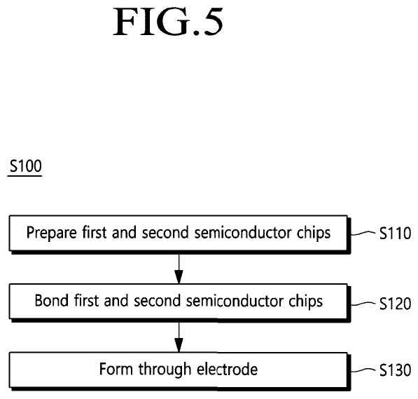

FIG. 5 is a flow chart showing a method S100 of manufacturing a semiconductor device according to an embodiment of the present disclosure.

Referring to FIG. 5, the method S100 may include preparing first and second semiconductor chips (S110), bonding the first and second semiconductor chips to each other (S120), and forming a through electrode (S130).

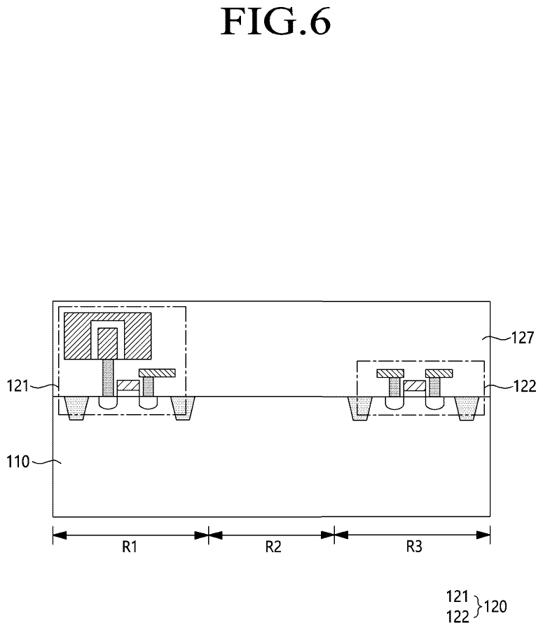

FIG. 6 to FIG. 17 are cross-sectional views illustrating, according a method for manufacturing a semiconductor device according to an embodiment of the present disclosure.

Referring to FIG. 6, a first substrate 110, a first circuit layer 120 (121, 122), and a first insulating layer 127 may be provided. The first circuit layer 120 may be configured on the upper surface of the first substrate 110. The first circuit layer 120 may include a first integrated circuit 121 that is disposed in a first region R1 and a second integrated circuit 122 that is disposed in a third region R3. The first insulating layer 127 may be disposed on the upper surface of the first substrate 110 and cover the first circuit layer 120. A second region R2 may be defined between the first region R1 and the third region R3.

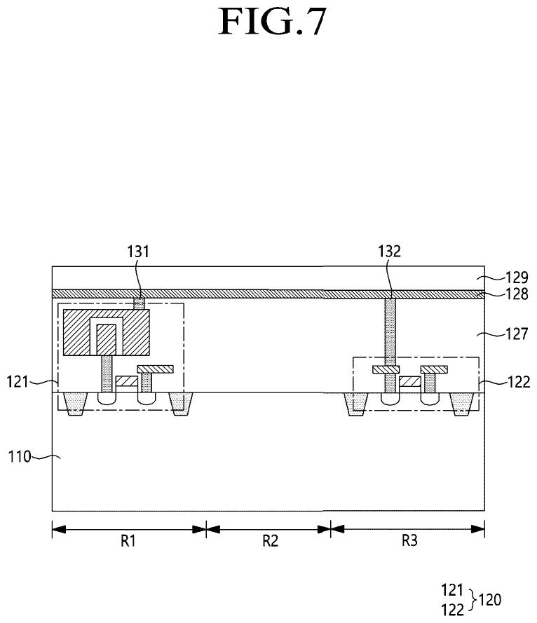

Referring to FIG. 7, first and second contacts 131 and 132 may be formed, and a first etch stop layer 128 and a second insulating layer 129 may be formed.

The first contact 131 may be connected to the first integrated circuit 121 by penetrating the first insulating layer 127, and the second contact 132 may be connected to the second integrated circuit 122 by penetrating the first insulating layer 127. The first and second contacts 131 and 132 extend inside the first insulating layer 127 in a direction perpendicular to a top surface of the substrate 110.

Forming the first and second contacts 131 and 132 may include forming contact holes in the first insulating layer 127 by a photolithography process and filling the contact holes with a conductive material.

The conductive material may include a metal material such as, for example, tungsten (W), titanium (Ti), aluminum (Al) or copper (Cu). A barrier metal may be additionally formed before filling the contact holes with the conductive material.

The first etch stop layer 128 may cover the first insulating layer 127 and the first and second contacts 131 and 132. The second insulating layer 129 may cover the first etch stop layer 128.

The first etch stop layer 128 may include an insulating material that has an etching selectivity different from the first and second insulating layers 127 and 129. The first and second insulating layers 127 and 129 may include, for example, an oxide, and the first etch stop layer 128 may include, for example, a nitride.

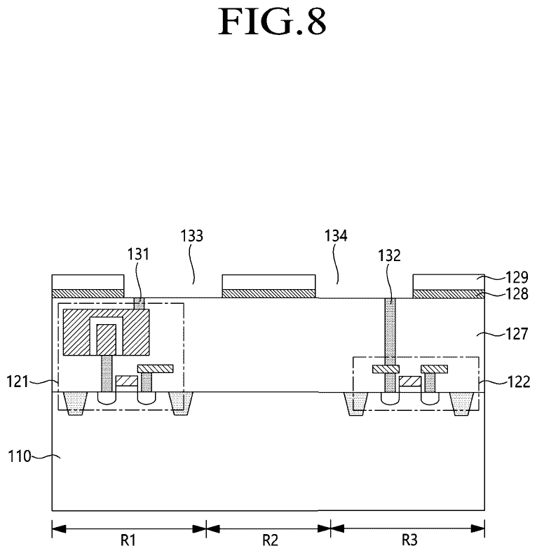

Referring to FIG. 8, first and second trenches 133 and 134 may be formed in the second insulating layer 129 and the first etch stop layer 128.

The first trench 133 may be formed to expose the first contact 131 and the first insulating layer 127 around the first contact 131. The second trench 134 may be formed to expose the second contact 132 and the first insulating layer 127 around the second contact 132. The first and second trenches 133 and 134 may be formed using a photolithography process.

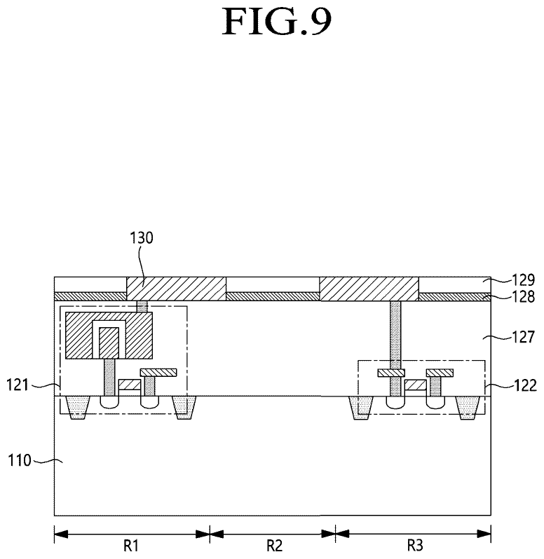

Referring to FIG. 9, a first chip pad 130 may be formed in each of the first and second trenches 133 and 134 (see FIG. 8).

Forming the first chip pad 130 may include forming a conductive material so that each of the first and second trenches 133 and 134 is filled and polishing the conductive material so that the second insulating layer 129 is exposed. The conductive material may be formed by a plating process. The polishing process may include a chemical mechanical polishing (CMP) process.

Before the conductive material is formed, a barrier metal may be formed on surfaces that are exposed by the first and second trenches 133 and 134. In this case, the barrier metal may be polished together with the conductive material during the polishing process.

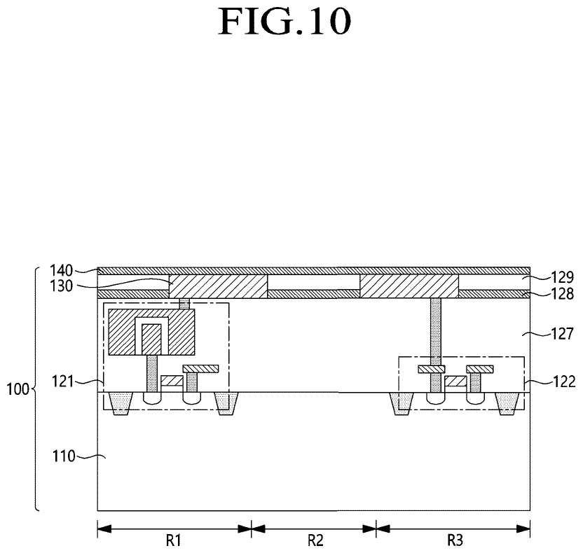

Referring to FIG. 10, a first bonding insulating layer 140 may be formed on the first chip pad 130 and the second insulating layer 129 of a first semiconductor chip 100. The first bonding insulating layer 140 may be, for example, a nitride layer. The first bonding insulating layer 140 may be provided as an oxidation prevention layer of the first chip pad 130. In this way, the first semiconductor chip 100 may be formed.

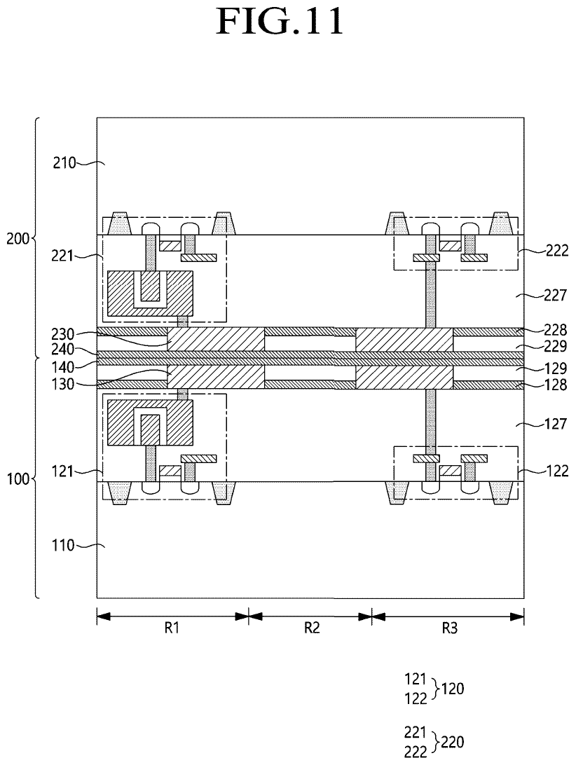

Referring to FIG. 11, a second semiconductor chip 200 may be bonded onto the first semiconductor chip 100. The second semiconductor chip 200 may have a mirror-symmetrical structure with respect to the first semiconductor chip 100. The second semiconductor chip 200 may be formed using the same process as the first semiconductor chip 100.

The second semiconductor chip 200 may include a second substrate 210, a second circuit layer 220 (221, 222), a third insulating layer 227, a second etch stop layer 228, a fourth insulating layer 229, a second chip pad 230, and a second bonding insulating layer 240.

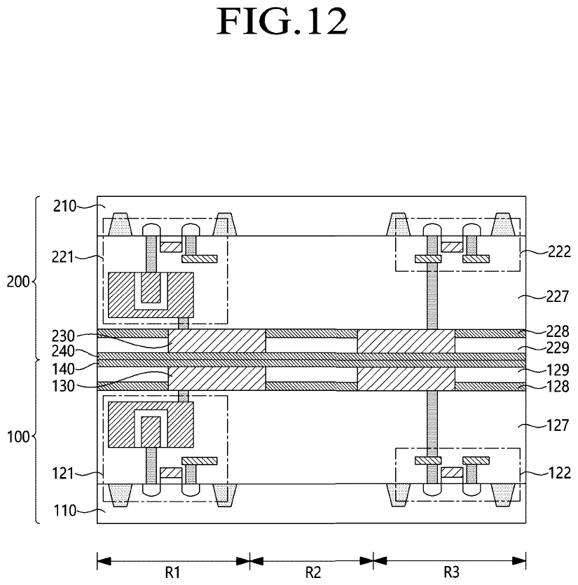

Referring to FIG. 12, the first substrate 110 and the second substrate 210 may be thinned.

In the thinning process, the lower surface of the first substrate 110 opposite to the upper surface of the first substrate 110 formed with the first circuit layer 120 may be polished, and the upper surface of the second substrate 210 opposite to the lower surface of the second substrate 210 formed with the second circuit layer 220 may be polished. The thinning process may include a chemical mechanical polishing process.

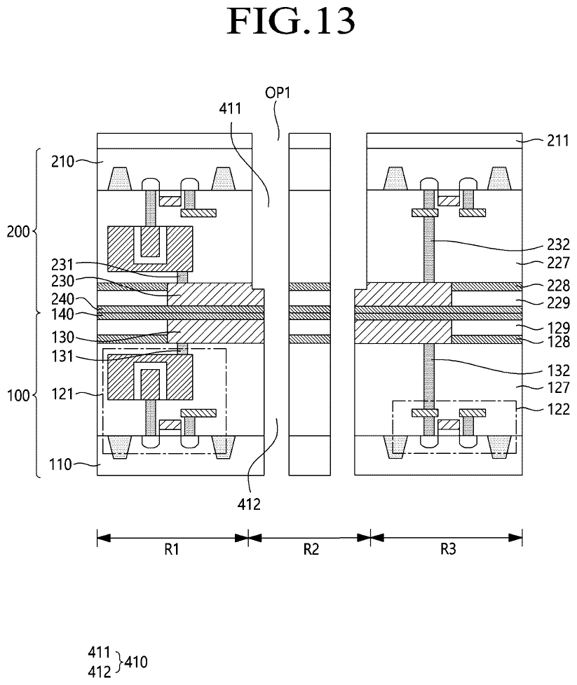

Referring to FIG. 13, a through hole 410 (411, 412) that penetrates the second semiconductor chip 200 and the first semiconductor chip 100 may be formed. The first and second chip pads 130 and 230 may be exposed through the through hole 410.

Forming the through hole 410 may include forming a mask pattern 211 having an opening OP1 on the second substrate 210, and etching the second and first semiconductor chips 200 and 100 using the mask pattern 211 as an etch mask.

The opening OP1 may vertically overlap a part of a corresponding second chip pad 230. Because the opening OP1 is formed to overlap with the second chip pad 230, the occurrence of a defect in which the first and second chip pads 130 and 230 are not exposed through the through hole 410 may be suppressed or prevented. In FIG. 13, the second chip pad 230 is partially etched during the etching process of forming the through hole 410, but the second chip pad 230 might not be etched.

The through hole 410 may expose a part of the upper surface of the second chip pad 230, the side surface of the second chip pad 230 and the side surface of the first chip pad 130.

The through hole 410 may include a wide width section 411 and a narrow width section 412. The wide width section 411 of the through hole 410 may penetrate the second substrate 210 and the third insulating layer 227. The narrow width section 412 of the through hole 410 may penetrate the fourth insulating layer 229, the second bonding insulating layer 240, the first bonding insulating layer 140, the second insulating layer 129, the first etch stop layer 128, the first insulating layer 127 and the first substrate 110.

The mask pattern 211 may be formed using photoresist, and the mask pattern 211 remaining after forming the through hole 410 may be removed by a strip process.

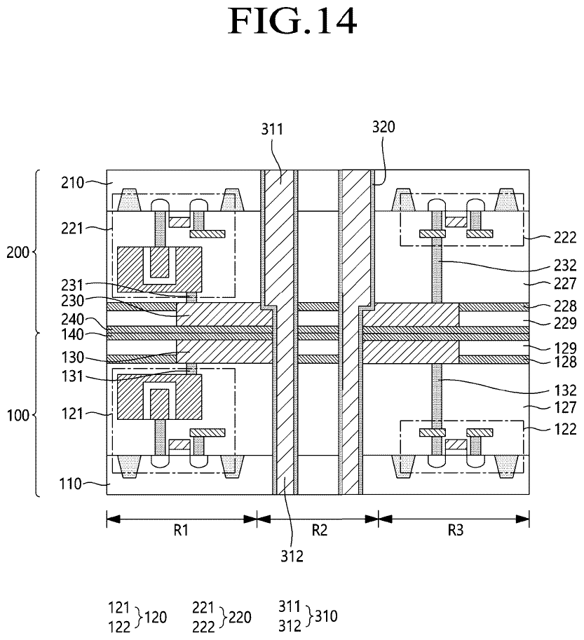

Referring to FIG. 14, a barrier metal 320 and a through electrode 310 (311, 312) may be formed. The through electrode 310 may include a wide width section 311 formed in the wide width section 411 of the through hole 410 and a narrow width section 312 formed in the narrow width section 412 of the through hole 410.

The barrier metal 320 may be formed on a surface that is exposed by the through hole 410 (see FIG. 13). The through electrode 310 may be formed by filling a conductive material into the through hole 410 (see FIG. 13). The through electrode 310 may be connected to the first and second chip pads 130 and 230 through the barrier metal 320.

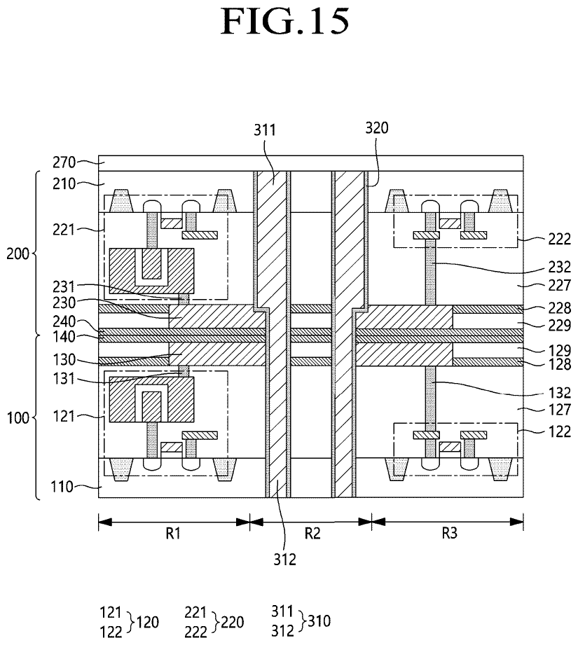

Referring to FIG. 15, a top insulating layer 270 may be formed.

The top insulating layer 270 may cover the upper surface of the second substrate 210 and the upper end of the through electrode 310.

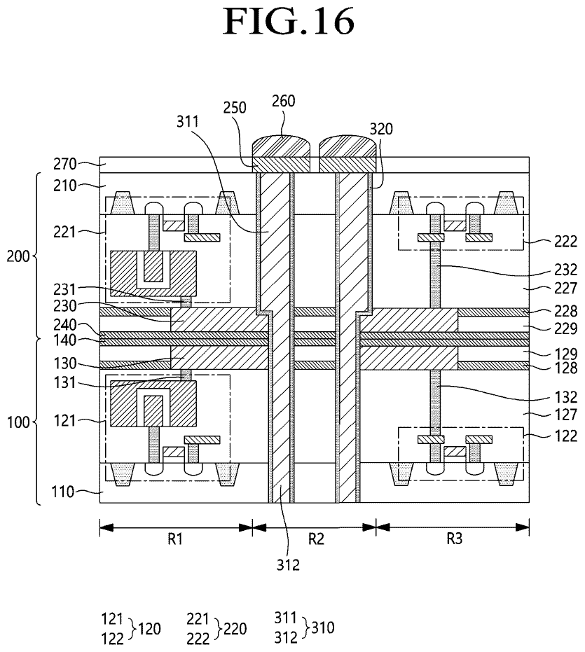

Referring to FIG. 16, a second connection pad 250 and a second connection member 260 may be formed.

Forming the second connection pad 250 may include forming a trench exposing the upper end of the through electrode 310 and the second substrate 210 around the upper end of the through electrode 310, in the top insulating layer 270 by a photolithography process, and forming a conductive material in the trench.

The second connection member 260 may be disposed on the second connection pad 250.

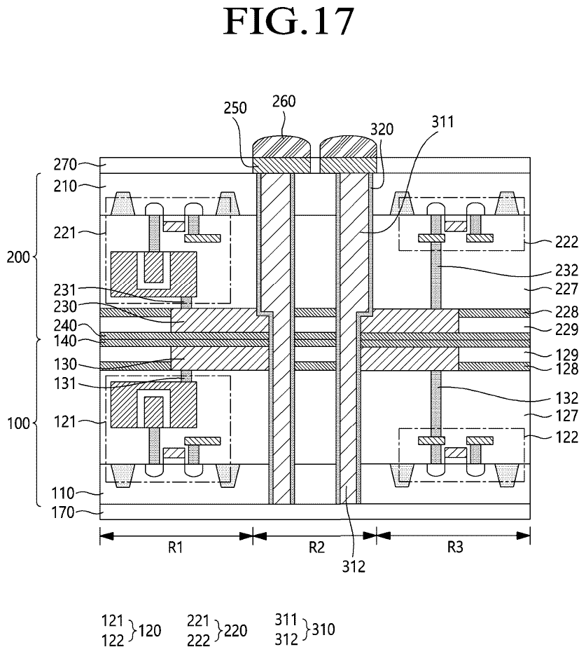

Referring to FIG. 17, a bottom insulating layer 170 may be formed to cover the lower surface of the first substrate 110 and the lower end of the through electrodes 310.

Referring again to FIG. 1, a first connection pad 150 and a first connection member 160 may be formed.

Forming the first connection pad 150 may include forming a trench exposing the lower end of the through electrode 310 and the first substrate 110 around the lower end of the through electrode 310, in the bottom insulating layer 170 by a photolithography process, and forming a conductive material in the trench.

The first connection member 160 may be disposed under the first connection pad 150.

In the embodiments described above with reference to FIG. 1 and FIG. 6 to FIG. 17, the second connection pad 250 and the second connection member 260 are formed first and the bottom insulating layer 170 is formed later. However, the bottom insulating layer 170 may be formed first and the second connection pad 250 and the second connection member 260 may be formed later.

According to embodiments of the present disclosure, first and second semiconductor chips that are included in a semiconductor device are directly bonded to each other, a chip pad of the first semiconductor chip and a chip pad of the second semiconductor chip are electrically connected by a through electrode that penetrates the first and second semiconductor chips, and a separate connection terminal (e.g., a bump or a solder layer) that connects the first semiconductor chip and the second semiconductor chip is not used. Therefore, compared to a case where a separate connection terminal that connects the first semiconductor chip and the second semiconductor chip is used, the heights of a semiconductor device and a semiconductor package including the same may be reduced.

It is possible to increase the number of semiconductor chips that may be disposed in a semiconductor package having a predetermined height, which may be advantageous for increasing capacity. Because it is possible to increase the thickness of individual semiconductor chips without increasing the height of a semiconductor package, it is possible to prevent the thickness of a chip from becoming excessively thin, thereby suppressing or preventing defects due to thinning of the thickness of the chip such as the warpage of the chip or chip cracking.

While detailed embodiments of the present disclosure are disclosed in the present disclosure, those skilled in the art will understand that various modifications, additions, and substitutions related to these embodiments are possible without departing from the scope and technical concepts of the present disclosure. Therefore, the scope of the present disclosure should not be limited to the foregoing embodiments. All changes within the meaning and range of equivalency of the claims are included within their scope.

What is claimed is:

1. A semiconductor device comprising:
a first semiconductor chip including a first substrate, a first circuit layer disposed on the first substrate and a first chip pad disposed on the first circuit layer;
a second semiconductor chip bonded onto the first semiconductor chip, and including a second substrate, a second circuit layer disposed under the second substrate and a second chip pad disposed under the second circuit layer; and
a through electrode penetrating the first semiconductor chip and the second semiconductor chip, and connected to the first chip pad and the second chip pad.

2. The semiconductor device according to claim 1, wherein
the first semiconductor chip further includes a first bonding insulating layer disposed on the first chip pad,
the second semiconductor chip further includes a second bonding insulating layer disposed under the second chip pad, and
an upper surface of the first bonding insulating layer and a lower surface of the second bonding insulating layer are bonded.

3. The semiconductor device according to claim 2, wherein each of the first bonding insulating layer and the second bonding insulating layer includes a nitride layer.

4. The semiconductor device according to claim 1,
wherein the second semiconductor chip further includes an insulating layer disposed between the second substrate and the second chip pad and covering the second circuit layer,
wherein the through electrode comprises:
a first section penetrating the second substrate and the insulating layer; and
a second section connected to the first section, and penetrating a bonding surface between the first semiconductor chip and the second semiconductor chip, and the first semiconductor chip, and
wherein a width of the first section is wider than a width of the second section.

5. The semiconductor device according to claim 4, wherein a part of the first section of the through electrode vertically overlaps with the second chip pad.

6. The semiconductor device according to claim 1, further comprising,
a barrier metal surrounding a side surface of the through electrode.

7. The semiconductor device according to claim 1, further comprising:
a first connection pad disposed under a lower surface of the first substrate opposite to an upper surface of the first substrate that is defined with the first circuit layer, and connected to the through electrode; and
a second connection pad disposed on an upper surface of the second substrate opposite to a lower surface of the second substrate that is defined with the second circuit layer, and connected to the through electrode.

8. The semiconductor device according to claim 7, further comprising:
a first connection member disposed under the first connection pad; and
a second connection member disposed on the second connection pad.

9. The semiconductor device according to claim 1, wherein an upper surface of the first chip pad is bonded with a lower surface of the second chip pad.

10. A semiconductor package comprising:
a base chip;
first and second semiconductor devices stacked on the base chip; and
a molding section disposed on the base chip, and sealing the first and second semiconductor devices,
wherein each of the first and second semiconductor devices comprises:
a first semiconductor chip including a first substrate, a first circuit layer disposed on the first substrate and a first chip pad disposed on the first circuit layer;
a second semiconductor chip bonded onto the first semiconductor chip, and including a second substrate, a second circuit layer disposed under the second substrate and a second chip pad disposed under the second circuit layer; and
a through electrode penetrating the first semiconductor chip and the second semiconductor chip, and connected to the first chip pad and the second chip pad.

11. The semiconductor package according to claim 10, further comprising,
a third semiconductor chip stacked on the second semiconductor device, and having a side surface surrounded by the molding section.

12. The semiconductor package according to claim 11,
wherein each of the first and second semiconductor devices further includes:
a first connection member disposed under a lower surface of the first substrate opposite to a upper surface of the first substrate that is defined with the first circuit layer, and connected to the through electrode; and
a second connection member disposed on an upper surface of the second substrate opposite to a lower surface of the second substrate that is defined with the second circuit layer, and connected to the through electrode,
wherein a third connection member disposed on the base chip is bonded with the first connection member of the first semiconductor device, and
wherein a fourth connection member disposed under the third semiconductor chip is bonded with the second connection member of the second semiconductor device.

13. The semiconductor package according to claim 10,
wherein each of the first and second semiconductor devices further includes:
a first bonding insulating layer on the first chip pad; and
a second bonding insulating layer under the second chip pad, and
wherein an upper surface of the first bonding insulating layer and a lower surface of the second bonding insulating layer are bonded.

14. The semiconductor package according to claim 10,
wherein the second semiconductor chip of each of the first and second semiconductor devices further includes an insulating layer disposed between the second substrate and the second chip pad and covering the second circuit layer,
wherein the through electrode of each of the first and second semiconductor devices comprises:
a first section penetrating the second substrate and the insulating layer; and
a second section connected to the first section, and penetrating a bonding surface between the first semiconductor chip and the second semiconductor chip and the first semiconductor chip, and
wherein a width of the first section is wider than a width of the second section.

15. The semiconductor package according to claim 14, wherein in each of the first and second semiconductor devices, a part of the first section of the through electrode vertically overlaps with the second chip pad.

16. A method of manufacturing a semiconductor device, comprising:
preparing first and second semiconductor chips each including a substrate, a circuit layer disposed on the substrate and a chip pad disposed on the circuit layer;
bonding the second semiconductor chip onto the first semiconductor chip; and
forming a through electrode that penetrates the first and second semiconductor chips to connect the chip pad of the first semiconductor chip and the chip pad of the second semiconductor chip.

17. The method according to claim 16, wherein
each of the first and second semiconductor chips further includes a bonding insulating layer on the chip pad, and
in the bonding the second semiconductor chip onto the first semiconductor chip, the bonding insulating layer of the first semiconductor chip and the bonding insulating layer of the second semiconductor chip are bonded to each other.

18. The method according to claim 16, wherein the forming a through electrode comprises:
forming, on the second semiconductor chip, a mask pattern that has an opening vertically overlapping with a part of the chip pad of the second semiconductor chip;
forming a through hole that penetrates the first and second semiconductor chips, by using the mask pattern as an etch mask; and
filling a conductive material into the through hole.
